(19) United States
(12) Patent Application Publication
(10) Pub. No.: US 2024/0218562 A1
(43) Pub. Date: Jul. 4, 2024

(54) METHODS OF PROCESSING EPITAXIAL SEMICONDUCTOR WAFERS

(71) Applicant: GlobalWafers Co., Ltd., Hsinchu (TW)

(72) Inventor: Manabu Hamano, Utsunomiya-City (JP)

(21) Appl. No.: 18/398,449

(22) Filed: Dec. 28, 2023

Related U.S. Application Data
(60) Provisional application No. 63/477,960, filed on Dec. 30, 2022.

(51) Int. Cl. C30B 25/16; C30B 25/10; C30B 25/12; C30B 25/14; C30B 25/18; C30B 29/06; H01L 21/02

(52) U.S. Cl. CPC C30B 25/165; C30B 25/10; C30B 25/12; C30B 25/14; C30B 25/186; H01L 21/02532; H01L 21/0262; C30B 29/06

(57) ABSTRACT

A method of processing semiconductor wafers includes placing a semiconductor wafer in a recess of a susceptor within a heated chamber. The recess is defined in the susceptor by a downwardly depending sidewall. The method also includes determining a distance of a peripheral edge of the wafer from the sidewall. The method also includes supplying a first process gas into the heated chamber at a first gas flow rate and a second process gas into the heated chamber at a second gas flow rate, and supplying heat to the heated chamber. The method also includes modulating the first gas flow rate, the second gas flow rate, and/or the heat supplied to the heated chamber to control a deposition rate of the first and second process gases near the peripheral edge of the wafer based on the determined distance of the peripheral edge of the wafer from the sidewall.

### CROSS-REFERENCE TO RELATED APPLICATION

This application claims priority to U.S. Provisional Patent Application No. 63/477,960, filed Dec. 30, 2022, the entire disclosure of which is incorporated by reference.

### FIELD

The field of the disclosure generally relates to semiconductor wafer processing, and more particularly to modulating process conditions during epitaxial processing based on semiconductor wafer placement location in a susceptor of an epitaxy chamber.

### BACKGROUND

Epitaxial chemical vapor deposition is a process for growing a thin layer of material on a semiconductor wafer so that the lattice structure is identical to that of the wafer. Using this process, a layer having different conductivity type, dopant species, or dopant concentration may be applied to the semiconductor wafer to achieve the necessary electrical properties.

Prior to epitaxial deposition, the semiconductor wafer is typically placed in a susceptor in a deposition chamber of a reactor. The epitaxial deposition process begins by introducing a cleaning gas to a front surface of the wafer to pre-heat and clean the front surface of the wafer. The cleaning gas removes native oxide from the front surface, permitting the epitaxial silicon layer to grow continuously and evenly on the surface during a subsequent step of the deposition process. The epitaxial deposition process continues by introducing a vaporous silicon source gas (e.g., trichlorosilane, SiHCl₃) to the front surface of the wafer to deposit and grow an epitaxial layer of silicon on the front surface. A back surface opposite the front surface of the susceptor may be simultaneously subjected to hydrogen gas. The susceptor, which supports the semiconductor wafer in the deposition chamber during the epitaxial deposition, is rotated during the process to ensure the epitaxial layer grows evenly.

Recently, there is increased demand for epitaxial semiconductor wafers with across-wafer uniformity in thickness and flatness, particularly in wafers used in complementary metal-oxide-semiconductor (CMOS) and integrated circuit device fabrication. Conventional systems and methods for epitaxial processing of semiconductor wafers remain limited in their ability to effectively and/or consistently produce the desired thickness and flatness uniformity of the deposited epitaxial layer. For example, conventional systems and methods may not adequately compensate for various factors of the epitaxial deposition process that negatively impact the thickness of the deposited epitaxial layer near the peripheral edge of the wafer. Edge roll-off may occur along the deposition surface of the wafer near the peripheral edge as a result, which degrades the uniformity in thickness and flatness of the epitaxial wafer.

A need exists for systems and methods that facilitate mitigating edge roll-off effects during epitaxial processing of a semiconductor wafer to improve uniformity in thickness and flatness of an epitaxial semiconductor wafer.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, these statements are to be read in this light, and not as admissions of prior art.

### BRIEF SUMMARY

One aspect is a method of processing semiconductor wafers within a heated chamber that includes a susceptor for supporting a semiconductor wafer. The susceptor has a front surface and a recess defined in the front surface by a downwardly depending sidewall. The method includes placing a semiconductor wafer in the recess of the susceptor and determining a distance of a peripheral edge of the wafer from the sidewall. The method also includes supplying a first process gas into the heated chamber at a first gas flow rate in a first gas direction and a second process gas into the heated chamber at a second gas flow rate in a second gas direction that intersects the first gas direction. The method also includes supplying heat to the heated chamber to induce deposition of the first and second process gases onto a surface of the wafer. The method also includes modulating at least one of the first gas flow rate, the second gas flow rate, and the heat supplied to the heated chamber to control a deposition rate of the first and second process gases near the peripheral edge of the wafer based on the determined distance of the peripheral edge of the wafer from the sidewall.

Another aspect is a method of processing semiconductor wafers within a heated chamber that includes a susceptor for supporting a semiconductor wafer. The susceptor has a front surface and a recess defined in the front surface by a downwardly depending sidewall. The method includes placing a semiconductor wafer in the recess of the susceptor. The method also includes determining a peripheral edge region of the wafer that is located a minimum distance from the sidewall. The method also includes supplying a first process gas into the heated chamber at a first gas flow rate in a first gas direction and a second process gas into the heated chamber at a second gas flow rate in a second gas direction that intersects the first gas direction. The method also includes modulating at least one of the first gas flow rate and the second gas flow rate to selectively increase a deposition rate of the first and second process gases near the peripheral edge region of the wafer is located the minimum distance from the sidewall.

Another aspect is a method of processing semiconductor wafers within a heated chamber that includes a susceptor for supporting a semiconductor wafer. The susceptor has a front surface and a recess defined in the front surface by a downwardly depending sidewall. The method includes placing a semiconductor wafer in the recess of the susceptor. The method also includes determining a peripheral edge region of the wafer that is located a minimum distance from the sidewall. The method also includes supplying process gas into the heated chamber and supplying heat to the heated chamber to induce deposition of the process gas onto a surface of the wafer. The method also includes modulating the heat supplied to the heated chamber to selectively increase a deposition rate of the process gas near the peripheral edge region of the wafer that is located the minimum distance from the sidewall.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a schematic cross-section of a heated chamber for processing semiconductor wafers.

FIG. 2 is a schematic cross-section of the heated chamber of FIG. 1, with elements omitted to show a semiconductor wafer supported on a susceptor in greater detail.

FIG. 3 is a schematic top view of the heated chamber of FIG. 1, with elements omitted to show the semiconductor wafer supported on the susceptor in greater detail.

FIG. 4 is a process flow of an example method of processing semiconductor wafers.

FIG. 5 is a graph illustrating modulation of localized heating within a heated chamber based on a distance between a peripheral edge of a semiconductor wafer and a recess sidewall of a susceptor within the heated chamber.

FIG. 6 is a graph that conceptually depicts normalized edge roll-off of epitaxial wafers that may be processed with and without the localized heating modulation illustrated in FIG. 5.

FIG. 7 is a graph illustrating modulation of a flow rate of trichlorosilane process gas within a heated chamber based on a distance between a peripheral edge of a semiconductor wafer and a recess sidewall of a susceptor within the heated chamber.

FIG. 8 is a graph that conceptually depicts normalized edge roll-off of epitaxial wafers that may be processed with and without the trichlorosilane gas flow rate modulation illustrated in FIG. 7.

FIG. 9 is a graph illustrating modulation of a flow rate of hydrogen chloride process gas within a heated chamber based on a distance between a peripheral edge of a semiconductor wafer and a recess sidewall of a susceptor within the heated chamber.

FIG. 10 is a graph that conceptually depicts normalized edge roll-off of epitaxial wafers that may be processed with and without the hydrogen chloride gas flow rate modulation illustrated in FIG. 9.

Corresponding reference characters indicate corresponding parts throughout the several views of the drawings.

### DETAILED DESCRIPTION

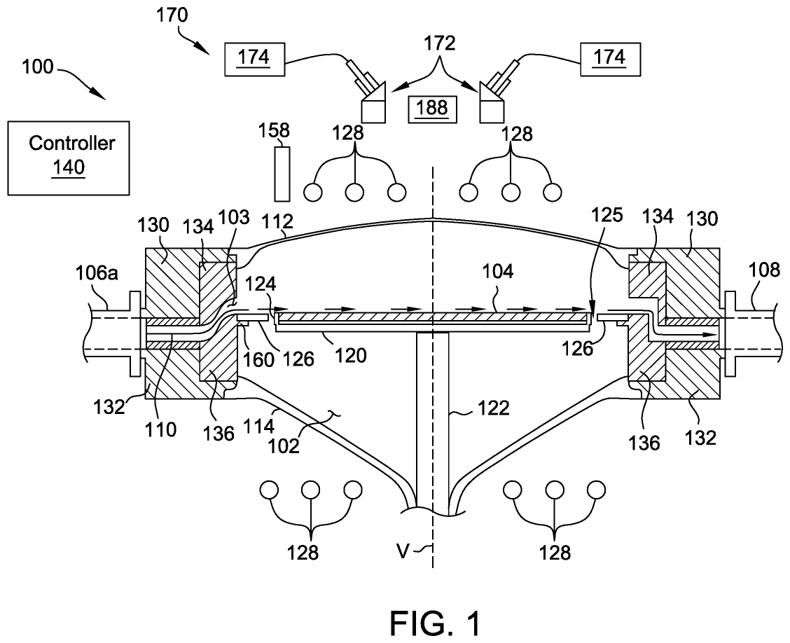

Referring to FIG. 1, an example heated chamber 100 for use in accordance with the present disclosure is shown. The heated chamber 100 may be, for example, a processing reactor, such as a deposition or a thermal treatment reactor, including vapor phase epitaxy processing reactors, for processing semiconductor wafers. The heated chamber 100 is an example and any reactor which permits a semiconductor wafer to be processed (e.g., facilitates depositing an epitaxial layer on a surface of the semiconductor wafer) according to the methods of the present disclosure may be used unless stated otherwise. In some examples, the heated chamber 100 may be a Centura Epi reactor available from Applied Materials (Santa Clara, CA).

The chamber 100 includes a processing environment 102 in which a single semiconductor wafer 104 is processed. For example, the chamber 100 may be suitable for semiconductor wafer processing such as chemical vapor deposition (CVD) growth (i.e., epitaxial growth) of a thin film on the wafer 104. Other suitable semiconductor wafer processing operations for the chamber 100 include, for example, heating of the wafer 104, cleaning of the wafer 104, and/or etching of the wafer 104. The chamber 100 may also be suitable for processing multiple (i.e., two or more) semiconductor wafers 104 simultaneously.

Suitable semiconductor wafers 104 (which may also be referred to as “wafers” or “silicon wafers”) include single crystal silicon wafers, such as, for example, silicon wafers obtained by slicing the silicon wafers from ingots formed by the Czochralski method or the float zone method. Each semiconductor wafer 104 includes a front surface 142 and a back surface 144 substantially parallel to the front surface 142. The front and back surfaces and 144 are generally 142 perpendicular to a central wafer 104. A circumferential or peripheral edge 146 joins the front and back surfaces 142 and 144. The semiconductor wafer 104 may have any suitable diameter including, for example, a 150 millimeter (mm), 200 mm, 300 mm, or 450 mm diameter.

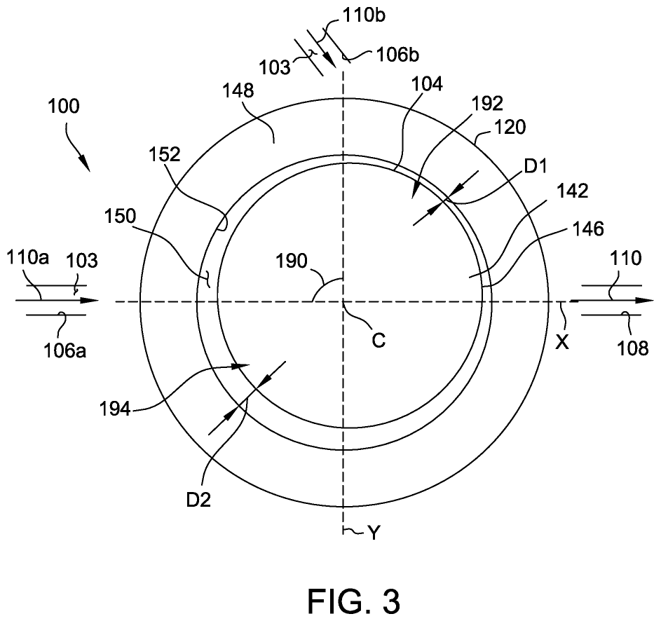

The chamber 100 includes a first gas injection port 106a disposed at one end of the processing environment 102, and a gas discharge port 108 disposed at an opposite end of the processing environment 102. The chamber 100 also includes a second gas injection port 106b (shown in FIG. 3) located between the first gas injection port 106a and the gas discharge port 108. A gas manifold (not shown) disposed between the gas injection ports 106a and 106b and the processing environment 102 is used to direct incoming gas 110 into the processing environment 102 enclosed by an upper window 112 and a lower window 114 through the first and second gas injection ports 106a and 106b.

In operation, an incoming process gas 110 flows through the gas manifold and into the processing environment 102 through a gas inlet 103 defined by each of the gas injection ports 106a and 106b. The gas 110 flows through the processing environment 102 and is discharged through the gas discharge port 108. The process gas 110 flowing through the inlets 103 respectively defined by the gas injection ports 106a and 106b may be the same or different.

The chamber 100 includes a susceptor 120 within the processing environment 102 for supporting a semiconductor wafer 104. The susceptor 120 is suitably configured for rotating the semiconductor wafer 104 during processing. For example, as shown in FIG. 3, the susceptor 120 is connected to a shaft 122 that is connected to a motor (not shown) of a rotation mechanism (not shown) for rotation of the shaft 122, the susceptor 120 and the semiconductor wafer 104 about a vertical axis V of the chamber 100. The susceptor 120 may rotate the semiconductor wafer 104 at any suitable rotational speed. For example, the susceptor 120 and the semiconductor wafer 104 may rotate at a rotational speed of between 1 RPM and 100 RPM. Additionally and/or alternatively, the susceptor 120 may be attached to a pair of rotatable supports (not shown) for rotating the susceptor 120 during processing.

The chamber 100 may also include a preheat ring 126 that surrounds the susceptor 120 within the processing environment 102. The preheat ring 126 may bring process gasses up to temperature before contacting the semiconductor wafer 104. The outside edge 124 of the susceptor 120 and an inside edge of the preheat ring 126 are separated by an annular gap 125 to allow rotation of the susceptor 120. The semiconductor wafer 104 is rotated to evenly process the wafer in the chamber 100.

Incoming gas 110 may be heated prior to contacting the semiconductor wafer 104. Both the preheat ring 126 and the susceptor 120 are generally opaque to absorb radiant heating light produced by high intensity radiant heating lamps 128 that may be located above and below the processing environment 102. Equipment other than high intensity lamps 128 may be used to provide heat to the processing environment 102 such as, for example, resistance heaters and inductive heaters. Maintaining the preheat ring 126 and the susceptor 120 at a temperature above ambient allows the preheat ring 126 and the susceptor 120 to transfer heat to the incoming gas 110 as the gas 110 passes over the preheat ring 126 and the susceptor 120. The diameter of the semiconductor wafer 104 is suitably less than the diameter of the susceptor 120 to allow the susceptor 120 to heat incoming gas 110 before it contacts the semiconductor wafer 104. The preheat ring 126 and susceptor 120 may be constructed of, for example, silicon carbide or opaque graphite coated with silicon carbide.

An infrared temperature sensor (e.g., sensor 188) such as a pyrometer may be mounted on the reaction chamber 100 to monitor the temperature of the susceptor 120, preheat ring 126, and/or the semiconductor wafer 104 by receiving infrared radiation emitted by the susceptor, the preheat ring, and/or the wafer.

The upper and lower windows 112, 114 each have a generally annular body made of a transparent material, such as quartz, to allow radiant heating light to pass into the processing environment 102 and onto the preheat ring 126, the susceptor 120, and the semiconductor wafer 104. The windows 112, 114 may be planar, or, as shown in FIG. 1, the windows 112, 114 may have a generally dome-shaped configuration. One or both of the windows 112, 114 may alternatively have an inwardly concave configuration. The upper and lower windows 112, 114 are coupled to upper and lower chamber walls 130, 132 of the chamber 100, respectively.

The upper and lower chamber walls 130, 132 define the outer perimeter of the processing environment 102, and abut the gas injection ports 106a and 106b and the gas discharge port 108.

The chamber 100 may include upper and lower liners 134, 136 disposed within the processing chamber to prevent reactions between the gas 110 and the chamber walls 130, 132 (which may be fabricated from metallic materials, such as stainless steel). The liners 134, 136 may be fabricated from suitably non-reactive materials, such as quartz. The outside circumference of the preheat ring 126 may be attached to the inner circumference of the lower liner 136. For example, the preheat ring 126 may be supported by an annular ledge 160 of the lower liner 136.

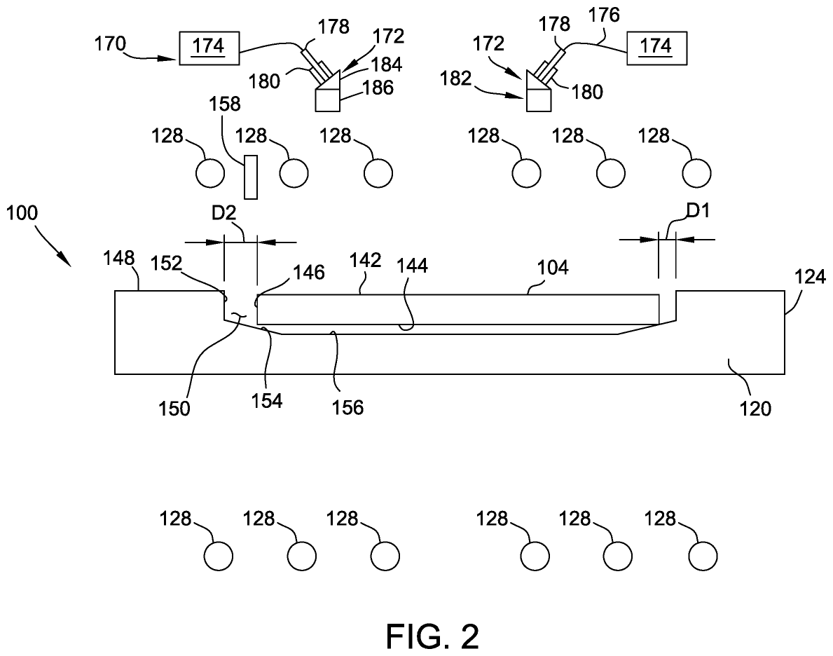

FIGS. 2 and 3 show the semiconductor wafer 104 supported on the susceptor 120 in the heated chamber 100 in greater detail. FIG. 2 is a cross-section of the heated chamber 100 and FIG. 3 is a top view of the heated chamber 100. Elements of the chamber 100 are omitted in FIGS. 2 and 3 for ease of illustration and description.

Referring to FIGS. 2 and 3, the susceptor 120 is substantially disk-shaped and includes a front surface 148 and a recess 150 formed in the front surface 148. The recess 150 is defined by a sidewall 152 that depends downwardly in the front surface 148. The recess 150 is sized and shaped for receiving the semiconductor wafer 104 during processing. For example, as shown in FIG. 3, the recess 150 is substantially circular and is defined by a substantially annular sidewall 152. The susceptor 120 may have other overall dimensions without departing from the scope of the present disclosure. The susceptor 120 may be sized and configured such that the recess 150 of the susceptor 120 can accommodate any suitable diameter semiconductor wafer 104 including, for example, 150 mm, 200 mm, 300 mm, or 450 mm diameter wafers 104.

The semiconductor wafer 104 is positioned within the recess 150 of the susceptor 120 and is supported by a ledge 154 extending between the sidewall 152 and a recess floor 156. The wafer 104 is oriented within the recess 150 such that the ledge 154 supports a portion of the back surface 144 of the wafer 104 proximate the peripheral edge 146. The ledge 154 slopes downwardly toward the recess floor 156 such that the floor 156 is spaced a distance from the back surface 144 of the wafer 104.

As shown in FIGS. 2 and 3, when the semiconductor wafer 104 is positioned in the recess 150, the peripheral edge 146 of the wafer is spaced a distance from the sidewall 152 of the susceptor 120. The semiconductor wafer 104 may be positioned in the recess 150 manually or using an automated wafer transfer device, such as a robotic arm. The wafer 104 may not be perfectly centered within the recess 150, such that a distance between the peripheral edge 146 and the sidewall 152 varies along the circumferential extent of the wafer 104. The peripheral edge 146 of the wafer 104 is spaced a minimum distance D₁ from the sidewall 152 and a maximum distance D₂ from the sidewall 152. The minimum distance D₁ and the maximum distance D₂ are different due to off-center wafer positioning in the recess 150. The off-center wafer positioning may be due to, for example, wafer placement tolerances, movement of the wafer during placement, and/or thermal expansion.

Referring generally to FIGS. 1-3, in operation, the heated chamber 100 containing the susceptor 120 and the wafer 104 supported on the susceptor 120 may be used for cleaning, etching, and/or growth steps of an epitaxial deposition process. In an example epitaxial deposition process, an epitaxial silicon layer is grown on the front surface 142 of the semiconductor wafer 104. In this example, the silicon wafer 104 is introduced into the processing environment 102 at atmospheric pressure and placed on the susceptor 120. A cleaning gas, such as hydrogen, H₂, or a mixture of H₂ and an etchant gas (e.g., hydrogen chloride, HCl), is introduced as the process gas 110 into the processing environment 102 through one or both of the first and second gas injection ports 106a and 106b to remove native oxide layers on the front and back surfaces 142 and 144 of the semiconductor wafer 104.

After the native oxide layers have been removed from both the front and back surfaces 142 and 144 of the semiconductor wafer 104, the cleaning gas is discontinued and the temperature in the heated chamber 100 is adjusted to a suitable temperature for an epitaxial deposition process (e.g., between about 600° C. and about 1200° C.). A deposition precursor gas is introduced as the process gas 110 through one or both of the first and second gas injection ports 106a and 106b. The deposition precursor gas may be a silicon-containing gas. Example silicon-containing gases include methyl silane, silicon tetrahydride (silane), trisilane, disilane, pentasilane, neopentasilane, tetrasilane, dichlorosilane (SiH₂Cl₂), trichlorosilane (SiHCl₃), silicon tetrachloride (SiCl₄), among others. The deposition precursor gas may include other materials, such as other semiconductor materials, depending on the targeted make-up of the deposited epitaxial layer. The concentration of the gas may be determined based on the desired deposition effects (e.g., deposition rate). The deposition precursor gas flows above the front surface 142 of the semiconductor wafer 104 at a suitable flow rate (e.g., between about 1 liter/minute and about 100 liters/minute) and for a duration sufficient to grow an epitaxial layer (e.g., an epitaxial silicon layer) on the front surface 302 of the semiconductor wafer 104. The epitaxial layer may have a thickness of between about 0.1 and about 200 micrometers. The processing environment 102 may be at a suitable pressure (e.g., atmospheric) during deposition.

The process gas 110 introduced to the processing environment 102 during a deposition process may include, in addition to the deposition precursor gas, a carrier gas such as hydrogen, H₂ (e.g., trichlorosilane in H₂). The carrier gas may additionally and/or alternatively include argon, nitrogen, helium, or combinations thereof. The carrier gas may contact the back surface 144 of the semiconductor wafer 104 and carry out-diffused dopant atoms from the back surface 144 toward the gas discharge port 108. The process gas 110 may also include an etchant gas, such as hydrogen chloride, HCl. The etchant gas may facilitate smoothing the deposited epitaxial layer. Etchant gas may also be created in the processing environment due to reaction between the carrier gas and the deposition precursor gas. For example, where the process gas 110 includes trichlorosilane in H₂, HCl may be created by the following equation:

SiHCl₃(g)+H₂(g)=Si(s)+3HCl(g).

The distance between the peripheral edge 146 of the wafer 104 and the sidewall 152 may cause edge roll-off of the deposited epitaxial layer near the peripheral edge of the wafer 104, which affects the uniformity in thickness and flatness of the wafer 104 post-epitaxy. For example, a smaller distance between the peripheral edge 146 and the sidewall 152 may result in a smaller amount of deposited material to accumulate near the peripheral edge 146 of the wafer 104, relative to the epitaxial layer deposited across the front surface 142. This creates in the deposited epitaxial layer near the peripheral edge 146. Without being bound by a particular theory, the downtick in the deposited epitaxial layer along regions near where the peripheral edge 146 is located a relatively smaller distance from the sidewall 152 may be due to less interaction between the process gas 110 and the peripheral edge 146 and/or a relatively lower temperature at the peripheral edge 146 due to the relatively lower temperature of the susceptor 120 at the sidewall 152. A greater distance between the peripheral edge 146 and the sidewall 152 may result in a greater amount of deposited material to accumulate near the peripheral edge 146 of the wafer 104, relative to the epitaxial layer deposited across the front surface 142. This creates an “uptick” in the deposited epitaxial layer near the peripheral edge 146. Without being bound by a particular theory, the uptick in the deposited epitaxial layer along regions near where the peripheral edge 146 is located a relatively greater distance from the sidewall 152 may be due to more interaction between the process gas 110 and the peripheral edge 146 as there is more space between the wafer 104 and the sidewall 152 for the process gas to flow.

Due to the different epitaxial deposition behavior depending on the distance between the peripheral edge 146 of wafer 104 and the sidewall 152 of the susceptor 120, off-center positioning of the wafer 104 within the recess 150 may affect the uniformity in thickness and flatness of the wafer 104 post-epitaxy. Alternatively stated, the edge roll-off of the deposited epitaxial layer may vary along the circumferential extent of the wafer 104 due to the off-center positioning within the recess 150. For example, regions (e.g., a region indicated generally at 194 in FIG. 3) on the front surface 142 of the wafer 104 near the peripheral edge 146 where the wafer 104 is spaced the maximum distance D₂ from the sidewall 152 may accumulate a relatively greater amount of deposited epitaxial material. Regions (e.g., a region indicated generally at 192 in FIG. 3) on the front surface 142 of the wafer 104 near the peripheral edge 146 where the wafer 104 is spaced the minimum distance D₁ from the sidewall 152 may accumulate a relatively smaller amount of deposited epitaxial material. As such, the deposited epitaxial layer may have upticks and downticks near the peripheral edge 146 along the circumferential extent of the wafer 104, resulting in non-uniform thickness and poor flatness of the wafer 104 post-epitaxy.

Still referring to FIGS. 1-3, the heated chamber 100 includes an optical sensor 158 for measuring a distance between the peripheral edge 146 of the wafer 104 and the sidewall 152 of the susceptor 120. The optical sensor 158 may be, for example, a camera. Suitably, the optical sensor 158 is located outside of the processing environment 102 and above the upper window 112. The optical sensor 158 may suitably measure the distance between the peripheral edge 146 and the sidewall 152 for the entire or for substantially the entire circumferential extent of the wafer 104. For example, the optical sensor 158 may take measurements at a single location between the peripheral edge 146 of the wafer 104 and the sidewall 152 and the optical sensor 158 continues to collect measurements as the wafer 104 is placed in and rotated by the susceptor 120. Although one optical sensor 158 is shown in this example, more than one (i.e., two or more) optical sensor 158 may be included. Each optical sensor 158 may collect measurements at different locations between the peripheral edge 146 and the sidewall 152.

The optical sensor 158 may collect measurements of the distance between the peripheral edge 146 and the sidewall 152 in any suitable manner. For example, the optical sensor 158 may be connected to a controller 140 that may determine a distance between the peripheral edge 146 and the sidewall 152 based on the measurements collected by the optical sensor 158. Additionally or alternatively, the optical sensor 158 may be connected to a user interface that displays the collected measurements to an operator. The measurements collected by the optical sensor 158 may be in units of length (e.g., metric units such as mm), or may be relative units. For example, the optical sensor 158 may collect measurements in arbitrary units against a reference distance. Thus, reference made to “measuring a distance,” “determining a distance,” “collecting measurements of a distance,” and the like, as it relates to the distance between the peripheral edge 146 and the sidewall 152, is not limited to a particular measurement technique. The measurements collected by the optical sensor 158 enable a determination of the regions along the circumferential extent of the wafer 104 where edge roll-off may occur. For example, the measurements collected by the optical sensor 158 may enable a determination of the wafer regions (e.g., the region 192 in FIG. 3) that are near the peripheral edge 146 where the wafer 104 is spaced the minimum distance D₁ from the sidewall 152 and wafer regions (e.g., the region 194 in FIG. 3) that are near the peripheral edge 146 where the wafer 104 is spaced the maximum distance D₂ from the sidewall 152.

In example methods, processing conditions within the heated chamber 100 are controlled and/or adjusted (collectively, “modulated”), using the controller 140 for example, based on the determined distance between the peripheral edge 146 of the wafer 104 and the sidewall 152 of the susceptor 120. The processing conditions may include, for example, a flow rate of the process gas 110 introduced to the processing environment 102 and/or heat supplied to the processing environment 102. The processing conditions are modulated to control a deposition rate of the process gas 110 near the peripheral edge 146 of the wafer 104 based on the determined distance between the peripheral edge 146 of the wafer 104 and the sidewall 152. Thereby, greater uniformity in thickness and flatness of the wafer 104 post-epitaxy may be achieved. For example, the processing conditions may be modulated to increase an amount of deposited material on regions of the wafer 104 near the peripheral edge 146 where the wafer 104 is at the minimum distance D₁ from the sidewall 152. The processing conditions may additionally or alternatively be modulated to decrease an amount of deposited material on regions of the wafer 104 near the peripheral edge 146 where the wafer 104 is at the maximum distance D₂ from the sidewall 152.

As shown in FIG. 1, the heated chamber 100 also includes the controller 140. The controller 140 is configured to control operation of the heated chamber 100 (e.g., by modulating one or more processing conditions of the heated chamber). The controller 140 may be configured to control operation of the heated chamber 100 based on the determined distance between the peripheral edge 146 of the wafer 104 and the sidewall 152 of the susceptor 120 to thereby control a deposition rate of the process gas 110 near the peripheral edge 146 of the wafer 104. For example, the controller 140 may modulate a flow rate of the process gas 110 introduced to the processing environment 102 and/or heat supplied to the processing environment 102 based on the determined distance between the peripheral edge 146 of the wafer 104 and the sidewall 152.

The controller 140 may include any suitable computer and/or other processing unit, including any suitable combination of computers, processing units and/or the like that may be communicatively connected to one another and that may be operated independently or in connection within one another (e.g., the controller 140 may form all or part of a controller network). The controller 140 may include one or more modules or devices, one or more of which is enclosed within a single housing, or may be located remote from one another. The controller 140 may include one or more processor (s) and associated memory device (s) configured to perform a variety of computer-implemented functions (e.g., performing the functions disclosed herein). As used herein, the term “processor” refers not only to integrated circuits, but also refers to a controller, a microcontroller, a microcomputer, a programmable logic controller (PLC), an application specific integrated circuit, and other programmable circuits. Additionally, memory device (s) of the controller 140 may be or include memory element (s) including, but not limited to, computer readable medium random (e.g., access memory (RAM)), computer readable non-volatile medium (e.g., a flash memory), a floppy disk, a compact disc-read only memory (CD-ROM), a magneto-optical disk (MOD), a digital versatile disc (DVD) and/or other suitable memory elements. Such memory device (s) may be configured to store suitable computer-readable instructions that, when implemented by the processor (s), configure or cause the controller 140 to perform various functions described herein including, but not limited to, controlling operating of the heated chamber 100.

The controller 140 may communicate with one or more components of the heated chamber 100 (e.g., the optical sensor 158, one or more spot heating modules 170, one or more gas injection ports 106a, b, the gas manifold, one or more temperature sensors 188, the rotation mechanism of the susceptor 120, and/or other components) via a communication interface coupled in communication with one or more of these components. The communication interface may include, without limitation, a wired network adapter, a wireless network adapter, a mobile telecommunications adapter, a serial communication adapter, or a parallel communication adapter. The communication interface may receive a data signal from, or transmit a data signal to, one or more components of the heated chamber 100 (e.g., the optical sensor 158, one or more spot heating modules 170, one or more gas injection ports 106a, b, the gas manifold, one or more temperature sensors 188, the rotation mechanism of the susceptor 120, and/or other components). The controller 140 may also include a presentation interface coupled to one or more of the processors. The presentation interface may present information, such as a user interface, to an operator of the heated chamber 100. In one embodiment, the presentation interface includes a display adapter (not shown) that is coupled to a display device (not shown), such as a cathode ray tube (CRT), a liquid crystal display (LCD), an organic LED (OLED) display, or an “electronic ink” display. In some embodiments, the presentation interface includes one or more display devices. In addition, or alternatively, the presentation interface includes an audio output device (not shown), for example, without limitation, an audio adapter, a speaker, or a printer (not shown). The controller 140 may also include a user input interface coupled to one or more of the processors and operable to receive input from the operator. The user input interface may include, for example, and without limitation, a keyboard, a pointing device, a mouse, a stylus, one or more input buttons, a touch sensitive panel, such as, without limitation, a touch pad or a touch screen, and/or an audio input interface, such as, without limitation, a microphone. A single component, such as a touch screen, may function as both a display device of the presentation interface and the user input interface.

Still referring to FIGS. 1-3, the heated chamber 100 may be configured such that localized heating within the processing environment 102 may be modulated to control the deposition rate of the process gas 110 near targeted regions of the wafer 104 based on the determined distance between the peripheral edge 146 of the wafer 104 and the sidewall 152. Localized heating may be controlled by independently controlling (e.g., using the controller 140) the high intensity radiant heating lamps 128 that may be located above and below the processing environment 102. Additionally or alternatively, localized heating may be controlled by selectively controlling (e.g., using the controller 140) select groups (or “radial zones”) of the heating lamps 128, in order to control the temperature of various regions of the semiconductor wafer 104 during processing. Independently controlling lamps 128, or controlling independent radial zones of the heating lamps 128, enables control of deposition thickness uniformity by adjusting local temperature at the reaction site to compensate, for example, for edge roll-off effects induced by the distance between the peripheral edge 146 and the sidewall 152. Heating lamps 128 or zones thereof may be separately powered using separate power supplies or by power division control among the zones.

The heated chamber 100 may also include a spot heating module 170. The spot heating module 170 includes one or more spot heaters 172. Each spot heater 172 supplies localized heat within the processing chamber 102. The spot heaters 172 are utilized to suitably supply localized heat near one or more targeted regions on the semiconductor wafer 104 during processing. The targeted regions of the wafer 104 for localized heat may be regions where the peripheral edge 146 is spaced a distance from the sidewall 152 such that edge roll-off is expected to occur. For example, the spot heaters 172 may be utilized to supply localized heat within the processing chamber 102 to target regions (e.g., a region indicated generally at 192 in FIG. 3) of the wafer 104 near the peripheral edge 146 where the wafer 104 is at the minimum distance D₁ from the sidewall 152. The spot heating module 170 may thereby facilitate more uniform epitaxial layer thickness and wafer flatness, by facilitating reducing or eliminating edge roll-off. Localized heating using the spot heaters 172 may be controlled via the controller 140.

Each spot heater 172 is connected to an electromagnetic radiant source 174, or multiple electromagnetic radiant sources 174, via corresponding optical fibers 176, for example. The electromagnetic radiant source 174 may be disposed directly on the spot heater 172 instead of connected to the spot heater 172 by an optical fiber. The electromagnetic radiant source 174 may be a pulsing electromagnetic radiant source or a continuous wave (CW) electromagnetic radiant source, for example. Additionally or alternatively, the electromagnetic radiant source 174 may be a high-energy radiant source, such as laser sources including, for example, crystal lasers, laser diodes and arrays, and vertical-cavity surface-emitting lasers (VCSELs). High intensity LED sources ma y also be used as the electromagnetic radiant source, and collimators may be used to collimate light emitted from the LED source to form a light beam. Wavelength of the emitted radiation may generally be in the ultraviolet, visible, and/or infrared spectrum, from about 200 nm to about 900 nm, for example 810 nm, and the emitted radiation may be monochromatic, narrow band, broadband, or ultra-broadband such as a white laser.

The electromagnetic radiant sources 174 emit high intensity electromagnetic radiation, which is routed to the spot heaters 172 via the optical fibers 176. The spot heaters 172 orient the outlet end of the optical fibers 176 toward a target location in the processing environment 102, such as on a targeted region of the wafer 104 placed on the susceptor 120. The optical fiber 176 produces a radiant beam from the radiation emitted by the electromagnetic radiant source 174 toward the target location. The end of the optical fiber 176 can have one or more optical features, including lenses, faceted surfaces, diffuse surfaces, filters and other coatings, to direct or condition the electromagnetic radiation exiting the fiber. Alternatively, one or more optical elements can be coupled to the end of the optical fiber 176 in the spot heater 172. The spot heater 172 is thus configurable and swappable. The radiant beams from the electromagnetic radiant sources 174 may have the same wavelength or different wavelengths. In one embodiment, the radiant beams have different wavelengths for heating regions of and/or different materials formed on the wafer 104.

As shown in FIG. 2, the spot heater 172 includes a collimator 178 held by a holder 180. The collimator 178 is an optical element that collimates radiation from one of the electromagnetic radiant sources 174, for example by use of appropriately designed lenses. The collimator 178 has a first end, into which radiation from the electromagnetic radiant source 174 is input, for example by directing the output of a laser source into an opening in the first end. The collimator 178 has a second end with an opening where a collimating optical assembly is housed. A laser or laser source may be directly mounted to the collimator 178 by inserting a beam exit portion of the laser into the first end of the collimator 178 such that the radiation emitted by the laser passes through the collimator 178 and exits through the second end with the collimating optical assembly, which may be a lens or a collection of lenses. The collimator 178 may alternatively be replaced with the optical fiber 176 or the electromagnetic radiant source 174, and the holder 180 then holds the fiber 176 or the electromagnetic radiant source 174 directly.

The holder 180 is disposed on a stage 182. The stage 182 includes a wedge 184 and a slider 186. The stage 182 is secured to the heated chamber 100, such as on a base or a support thereof. For example, the stage 182 may be secured to a top cover of the heated chamber 100 that encloses processing equipment such as the heating lamps 128. Additionally and/or alternatively, the stage 182 may be secured to a reflector disposed over processing equipment (e.g., the heating lamps 128) of the heated chamber 100. The slider 186 enables linear movement of the stage 182 relative to the heated chamber 100 during processing. The slider 186 may be linearly moveable using set screws or an actuator, for example.

The wedge 184 includes a surface that is in contact with the holder 180. The surface of the wedge 184 forms an angle with respect to a plane that is substantially parallel to the front surface 148 of the susceptor 120. The angle formed by the surface of the wedge 184 may be adjusted, for example, by an actuator located in the wedge 184. Adjusting this angle enables targeting of the localized heating by the spot heater 172. Targeting of the spot heater 172 may also be accomplished by adjusting the location of the stage 182 via slider 186. Because the angle formed by the surface of the wedge 184 and the location of the slider 186 can be adjusted by actuators, the location of a beam spot emitted by the spot heater 172 may be adjusted during processing. The wedge 184, the slider 186, and the support of the heated chamber 100 to which the stage 182 is secured may each be fabricated from a material that is transparent to the radiation of the radiant energy emitted from the electromagnetic radiant source 174 (transmitting at least 95% of the radiation of the radiant energy), such as quartz. Additionally and/or alternatively, an opening may be formed through the wedge 184, the slider 186, and the support of the heated chamber 100 for a beam, such as a laser beam, from the collimator 178 to pass therethrough to a target area on the semiconductor wafer 104. The opening is suitably large enough to accommodate the movement of the wedge 184 and/or the slider 186.

The spot heater 172 can be aimed by performing a manual alignment process. During the alignment process, the spot heater 172 is energized to produce a guide beam. An operator may view a spot of light from the guide beam landing on the susceptor 120. The susceptor 120 may be rotated to align the region to be heated by the spot heater 172 with the guide beam. The positioning devices of the spot heater 172, such as the slider 186 and the wedge 184, may then be operated to align the spot heater 172 to a targeted region to be heated. For example, the targeted region to be heated may be a region (indicated generally at 192 in FIG. 3) of the wafer 104 near the peripheral edge 146 where the wafer 104 is at the minimum distance D₁ from the sidewall 152.

The collimator 178 may be connected to a movement device (not shown) that facilitates movement of the collimator 178 within the holder 180. The movement device may be disposed between the holder 180 and the collimator 178. The movement device may be, for example, a device that rotates the collimator 178 about a longitudinal axis the of collimator 178. During processing, the collimator 178 may be at a first position during a first processing step, and the collimator 178 may be rotated to a second position before or during a second processing step. Rotating of the collimator 178 may change the shape and/or size of the beam spot of a radiant beam exiting the collimator 178 onto the susceptor 120 and/or the wafer 104, for example. The movement device may continuously rotate the collimator 178 about the longitudinal axis of the collimator 178 (e.g., in a clockwise or counterclockwise rotational direction) during processing to dynamically change the shape of the beam spot. As discussed above, the susceptor 120 and the wafer 104 may also be rotated during processing. The rotation of the collimator 178 may be synchronized with the rotation of the wafer 104 in order to provide precise heating of one or more targeted regions on the wafer 104. Additionally and/or alternatively, the movement device may cause the collimator 178 to rotationally oscillate within a predetermined angular range, such as between negative 60 degrees to 60 degrees. The oscillation of the collimator 178 may be synchronized with the rotation of the wafer 104. The movement device may also be coupled to the fiber 176 or the electromagnetic radiant source 174 in examples where the collimator 178 is replaced with the fiber 176 or the electromagnetic radiant source 174. The movement device may rotate the fiber 176 or the electromagnetic radiant source 174 as described above for the collimator 178.

The movement device for the collimator 178 can be a controlled motion device that produces a periodic motion, such as vibration, circular motion, or linear motion. The motion produced by the movement device is transferred to the collimator 178, or alternatively, the fiber 176 or the electromagnetic radiation source 174. The collimator 178 may move the beam spot as the movement device moves the collimator 178. The movement of the beam spot suitably irradiates an exposure area on the wafer 104 that is larger than an area of the beam spot. Additionally and/or alternatively, the collimator 178 may irradiate overlapping regions on the wafer 104, approximating irradiation by a large beam spot larger than the beam spot produced by the electromagnetic radiant source 174. When the collimator 178 moves, the electromagnetic radiant source 174 produces a continuous electromagnetic radiant beam that irradiates an exposure area on the wafer 104 that is larger than an area of the beam spot as electromagnetic radiant beam passes through the moving collimator 178. The large beam spot defines an annular heating zone as the wafer 104 rotates during processing.

The electromagnetic radiant source 174 may be pulsed through the moving collimator 178 to form a large beam spot on the wafer 104 as the electromagnetic radiant beam passes through the moving collimator 178. The large beam spot heats discrete areas on the wafer 104 as the wafer 104 rotates during processing. The pulsing of the electromagnetic radiant beam may be synchronized with the rotation of the wafer 104 and/or with movement of the beam spot. For example, pulsing of the beam may be set to a frequency related to a frequency of vibration of the collimator 178. The related frequencies may deliver radiation pulses to overlapping areas of the wafer 104 such that an exposure area of the wafer 104, larger than an area of any of the pulses, is exposed to pulsed radiation. Duration of the pulsing through the moving collimator 178 determines an angular sweep of the exposure along an annular, or partially annular, heating zone.

The collimator 178 may move continuously or periodically, such as when a pulse of the electromagnetic radiant beam passes through the collimator 178. In one example, the beam may be pulsed for a first duration while the collimator 178 moves, and a second duration while the collimator 178 does not move. In this example, a first exposure area of the wafer 104 corresponding to the first duration is larger than an area of the beam, while a second exposure area corresponding to the second duration has a dimension that is the substantially the same as a dimension of the beam.

Example methods described herein may include modulating localized heating of the wafer 104 by adjusting the shape and/or size of a beam spot emitted by a spot heater 172 for heating radiation. The spot heater 172 is configured to control the shape and/or size of the beam spot dynamically without modifying the optics of the system.

A beam spot may also be formed by multiple (e.g., two) spot heaters 172 that are positioned and oriented such that the beam spots produced by each spot heater 172 overlap. The co-operating spot heaters 172 may include electromagnetic radiant sources 174 that produce radiant at beams the or same different wavelengths. For example, two co-operating spot heaters 172 may include a blue laser and a green laser, respectively, and the beam spot produced by overlapping beam spots includes a blue portion and a green portion.

A beam spot may also be formed by moving the collimator 178 and/or by actuating, for example vibrating, the slider 186. The beam spot may also be formed by actuating, for example moving, the angle that the surface of the wedge 184 forms with a plane that is substantially parallel to the front surface 148 of the susceptor 120. Moving of the collimator 178, the slider 186 and/or the angle of the surface of the wedge 184 may suitably form a racetrack-shaped beam spot. A pair of wedges 184 of co-operating spot heaters 172 may be precisely machined with an offset angle to achieve a desired beam spot shape.

Beam spots produced by one or more spot heaters 172 may have different orientations with respect to the movement of the wafer 104 during processing. For example, a beam spot may have a shape of an ellipse and the major axis of the ellipse-shaped beam spot may be oriented substantially perpendicular to the direction of movement of the wafer 104 (e.g., rotational direction). When the major axis of the beam spot is substantially perpendicular to the direction of the movement of the wafer 104, the width of the beam spot (i.e., the effective length of the major axis of the beam spot) can be adjusted without making changes to the optics of the spot heater (s) 172. For example, the width of the beam spot may be changed by rotating the collimator 178. Rotating the collimator 178 may cause the beam spot orientation to rotate such that the major axis of the ellipse shaped spot no longer is beam substantially perpendicular to the direction f the movement of the wafer 104, leading to a narrower width of the beam spot. This technique also works for linear beam spots.

The heated chamber 100 may also include one or more sensors 188, such as pyrometers, that are disposed on the support (e.g., a top cover or a reflector) of the chamber 100 to which the one or more spot heaters 172 are secured. Each spot heater 172 may also include a sensor 188. Both the collimator 178 and the sensor 188 may be disposed on a single stage 182. The one or more sensor 188 may be used (e.g., by the controller 140) to modulate power to the spot heater 172. For example, the controller 140 may receive temperature data from the sensors 188, and may increase or reduce power to the spot heater 172 based on the temperature data. In such a system, the combination of sensors 188 and spot heater 172 can be used in closed-loop or open-loop control to adjust the spot heater 172 based on a reading from the sensors 188.

In example methods, localized heating within the processing environment 102 may be modulated (e.g., using the controller 140) based on the determined distance between the peripheral edge 146 of the wafer 104 and the sidewall 152 of the susceptor 120 to control a deposition rate at different regions of the wafer 104 near the peripheral edge 146. Thereby, greater uniformity in thickness and flatness of the wafer 104 post-epitaxy may be achieved. For example, the controller 140 may modulate localized heating to increase an amount of deposited material on regions (e.g., the region 192 in FIG. 3) of the wafer 104 near the peripheral edge 146 where the wafer 104 is at the minimum distance D₁ from the sidewall 152. This may be accomplished by controlling one or more of the high intensity radiant heating lamps 128 and/or one or more spot heaters 172 of the spot heating module 170 to selectively increase localized heating within the processing environment 102 near the peripheral edge regions of the wafer 104 located the minimum distance D₁ from the sidewall 152. Additionally or alternatively, the controller 140 may modulate localized heating to decrease an amount of deposited material on regions (e.g., the region 194 in FIG. 3) of the wafer 104 near the peripheral edge 146 where the wafer 104 is at the maximum distance D₂ from the sidewall 152. This may be accomplished by controlling one or more of the high intensity radiant heating lamps 128 and/or one or more spot heaters 172 of the spot heating module 170 to selectively decrease localized heating within the processing environment 102 near the peripheral edge regions of the wafer 104 located the maximum distance D₂ from the sidewall 152. As described above, the susceptor 120 and the wafer 104 may be rotated within the processing environment 102. The controller 140 may control modulation of the localized heating to be synchronized with rotation of the susceptor 120 and the wafer 104.

Referring to FIG. 3, the heated chamber 100 may also be configured such that flow rates of and flow interaction between process gases 110 flowing within the processing environment 102 may be modulated (e.g., via the controller 140) to control the deposition rate of the process gas 110 near targeted regions of the wafer 104 based on the determined distance between the peripheral edge 146 of the wafer 104 and the sidewall 152. Flow interaction between the process gas 110 is facilitated by the first and second gas injection ports 106a and 106b. The gas injection ports 106a and 106b may also be referred to as gas inlet ports 106a and 106b. The first gas injection port 106a supplies a first process gas 110a into the processing environment 102 in a first gas direction and the second gas injection port 106b supplies a second process gas 110b into the processing environment 102 in a second gas direction that intersects the first gas direction. The intersection between the first and second process gases 110a and 110b creates a cross-flow interaction of the process gases within the processing environment 102, suitably over the front surface 142 of the wafer 104. Controlled flow interaction between the process gases within the processing environment 102 may provide advantages such as controlling thickness and/or compositional uniformity of the deposited epitaxial layer.

As shown in FIG. 3, the susceptor 120 defines an X axis and a Y axis. The X and Y axes are substantially perpendicular to each other and intersect at a center C of the susceptor 120. Each of the X and Y axes extends across the front surface 148 and the recess 150 of the susceptor 120. The first gas inlet port 106a and the gas discharge port 108 are disposed on opposing sides of the susceptor 120 and substantially aligned along the X axis. The second gas inlet port 106b is disposed between the first gas inlet port 106a and the gas discharge port 108 to supply the second process gas 110b at an angle to the first process gas 110a supplied by the first gas inlet port 106a. The second gas inlet port 106b and the first gas inlet port 106a are separated by an azimuthal angle 190. The azimuthal angle 190 may be any angle to facilitate the heated chamber 100 to function as described herein. For example, the azimuthal angle 190 may be between 0 and 145 degrees, measured on either side of the susceptor 120. In the example shown in FIG. 3, the azimuthal angle 190 is about 90 degrees. The positioning of the second gas inlet port 106b in FIG. 3 is an example and the second gas inlet port 106b may include other positions relative to the first gas inlet port 106a.

The first gas inlet port 106a supplies the first process gas 110a over the front surface 142 of the wafer 104 in a first direction, generally indicated by the arrow 110a. The term “process gas” refers to both a singular gas and a mixture of multiple gases. For example, the process gas 110a may include a deposition gas (e.g., precursor trichlorosilane, TCS) in combination with a carrier gas (e.g., H₂) and/or an etchant gas (e.g., HCl). The term “direction” means the direction in which a process gas exits an inlet port. Upon exiting the respective inlet port, at least a portion of the process gas may suitably deviate from the exiting direction within the processing environment 102 to cover the front surface 142 of the wafer 104. In the example chamber 100, the first direction of the first process gas 110a is substantially parallel to the front surface 142 of the wafer 104 and generally directed towards the opposing gas discharge port 108.

The first gas inlet port 106a may include a single port that defines the gas inlet 103 wherein the first process gas is provided therethrough, as shown schematically in FIG. 3, or may include a plurality of secondary inlets (not shown) that collectively define the gas inlet 103. For example, the first gas inlet port 106a may include up to 5 inlets, although greater or fewer secondary inlets may be provided (e.g., one or more). Each secondary inlet may provide the first process gas 110a, which may for example be a mixture of several process gases. Additionally and/or alternatively, one or more secondary inlets may provide one or more process gases 110a that are different than at least one other secondary inlet. The process gases supplied by the first gas inlet port 106a may mix substantially uniformly after exiting the first gas inlet port 106a to form the first process gas 110a. For example, the process gases may generally not mix together after exiting the first gas inlet port 106a such that the first process gas 110a has a purposeful, non-uniform composition. Flow rate, process gas composition, and the like, at the first gas inlet port 106a, or at each secondary inlet thereof, may be independently controlled. In some embodiments, some of the secondary inlets may be idle or pulsed during processing, for example, to achieve a desired flow interaction with the second process gas 110b provided by the second inlet port 106b. Further, in embodiments where the first gas inlet port 106a comprises a single port, the single port may be modulated (e.g., pulsed or by restricting flow therethrough) to achieve a desired flow interaction with the second process gas 110b.

The second gas inlet port 106b may be identical or substantially similar in design to the first gas inlet port 106a. As described above for the first gas inlet port 106a, the second gas inlet port 106b may include a single port, as shown schematically in FIG. 3. Additionally and/or alternatively, the second gas inlet port 106b may include a plurality of secondary inlets, as described above for the first gas inlet port 106a. Each secondary inlet may provide the second process gas 110b, or one or more process gases that are different than at least one other secondary inlets. The process gases may mix substantially uniformly after exiting the second gas inlet port 106b to form the second process gas 110b. The process gases may generally not mix together after exiting the second gas inlet port 106b such that the second process gas 110b has a purposeful, non-uniform composition. Flow rate, process gas composition, and the like, at the second gas inlet port 106b, or at each secondary inlet thereof, may be independently controlled. The second gas inlet port 106b, or some or all of the secondary inlets thereof, may be idle or pulsed during processing, for example, to achieve a desired flow interaction with the first process gas 100a provided by the first gas inlet port 106a.

The second gas inlet port 106b supplies the second process gas 110b in the second direction that intersects the first direction. Suitably, the second direction intersects the first direction such that a cross-flow interaction between the first and second process gases 110a and 110b occurs over the front surface 142 of the wafer 104. A relationship between the first direction of the first process gas 110a and the second direction of the second process gas 110b can be at least partially defined by the azimuthal angle 190. The azimuthal angle 190 is measured between the exit of the first gas inlet port 106a and the exit of the second gas inlet port 106b, about a central axis of the susceptor 120 (i.e., the axis extending substantially perpendicular to the X and Y axes and intersecting each at the center C). The azimuthal angle 190 may be up to about 145 degrees, or between about 0 to about 145 degrees. For example, the azimuthal angle 190 may be less than 90 degrees resulting in a location of the second gas inlet port 106b that is in a closer proximity to the first gas inlet port 106a than to the gas discharge port 108. In another example, the azimuthal angle 190 may be greater than 90 degrees resulting in a location of the second gas inlet port 106b that is in a closer proximity to the gas discharge port 108 than to the first gas inlet port 106a. In other examples, and as shown in FIG. 3, the azimuthal angle 190 is about 90 degrees. The azimuthal angle 190 may be selected to provide a desired amount of cross-flow interaction between the first and second process gases 110a and 110b.

Either or both of the first and second directions of the first and second process gas 110a and 110b, respectively, may be substantially parallel to the front surface 142 of the wafer 104, or at an angle with respect to the front surface 142 of the wafer 104 (i.e., at an angle relative to an X-Y plane defined by the X and Y axes). For example, the first gas inlet port 106a may have one or more secondary inlets oriented such that the first direction is at an angle with respect to the X-Y plane, and/or the second gas inlet port 106b may have a similar configuration orienting one or more of the secondary inlets such that the second direction is at an angle with respect to the X-Y plane.

In one example, the azimuthal angle 190 is zero degrees. In such an example, the first and second gas inlet ports 106a and 106b may be disposed in vertical alignment, for example, stacked atop each other or integrated into a single unit. In such embodiments, the first and second directions are different (even though the azimuthal angle 190 between them is zero degrees) due to the angled orientation of the second direction and the parallel orientation of the first direction with respect to the X-Y plane, and/or due to the angled orientation of the first direction and the parallel orientation of the second direction with respect to the X-Y plane. Accordingly, a flow interaction may occur between the first and second process gases 110a and 110b even at an azimuthal angle 190 of 0 degrees.

The azimuthal angle 190 may define the difference between the first and second directions of the first and second process gases 110a and 110b. For example, where the first and second direction are both parallel to the X-Y plane and the first gas inlet port 106a and the second gas inlet port 106b are oriented such that the first and second directions each aligns across a diameter of the susceptor 120 (and/or the wafer 104), the azimuthal angle 190 generally defines the flow interaction angle. In these examples, the azimuthal angle 190 is suitably non-zero such that the first and second direction are different, and thus a flow interaction can be achieved.

The first and second gas inlet ports 106a and 106b may be disposed at different heights to further facilitate flow interaction between the first and second process gases 110a and 110b. For example, the first gas inlet port 106a may be disposed at a first height and the second inlet port 106b may be disposed at a second height above the front surface 142 of the wafer 104. The first and second heights may be adjustable, for example, each height may be set prior to processing the wafer 104 in the chamber 100, or each inlet port 106a and 106b may mounted on a movable platform (not shown), or the susceptor 120 may be moved along the central axis thereof to adjust the first and second height (for example, where the susceptor 120 is vertically movable to place the wafer 104 in different processing planes). The second height of the second gas inlet port 106a may be greater than, less than, or equal to the first height of the first gas inlet port 106a. In such embodiments, the second direction of the second process gas 110b may be parallel to or angled with respect to the X-Y plane.

In the example shown in FIG. 3, the first gas inlet port 106a is oriented such that the first direction of the first process gas 110a is substantially aligned with a diameter of the susceptor 120 and/or the wafer 104. For example, the first direction substantially aligns with the X axis. The second gas inlet port 106b is angled with respect to the central axis of the susceptor 120 (i.e., the axis extending substantially perpendicular to the X and Y axes and intersecting each at the center C). As such, the second direction does not align with a diameter of the susceptor 120 and/or the wafer 104. In other examples, the second gas inlet port 106b may be oriented such that the second direction aligns with the diameter of the susceptor 120 and/or the wafer 104 (e.g., the second direction may substantially align with the Y axis). In these examples, the first gas inlet port 106a may be oriented as described above or the first gas inlet port 106a may be angled with respect to the central axis of the susceptor 120.

The second gas inlet port 106b may be angled with respect to the central axis such that the second direction points toward a region of the wafer 104 near the peripheral edge 146 where the wafer 104 is spaced the minimum distance D₁ from the sidewall 152, indicated generally at 192 in FIG. 3. The region 192 may also be referred to herein as a first peripheral edge region 192. The orientation of the first and second gas inlet ports 106a and 106b may increase cross-flow interaction between the first and second process gases 110a and 110b near the first peripheral edge region 192 of the wafer 104 where a smaller amount of epitaxial material may otherwise be deposited due to the minimum distance D₁ of the peripheral edge 146 from the sidewall 152. Increasing the cross-flow interaction between the first and second process gases 110a and 110b at the first peripheral edge region 192 may be suitable where both process gases 110a and 110b include a deposition precursor gas (e.g., trichlorosilane, TCS), such that a deposition rate of the first and second process gases 110a and 110b near the first peripheral edge region 192 of the wafer 104 may be increased. Additionally or alternatively, the cross-flow interaction between the first and second process gases 110a and 110b that both include a deposition precursor gas may decrease near a region of the wafer 104 near the peripheral edge 146 where the wafer 104 is spaced the maximum distance D₂ from the sidewall 152, indicated generally at 194 in FIG. 3. The region 194 may also be referred to herein as a second peripheral edge region 194. The decreased cross-flow interaction may decrease at the second peripheral edge region 194 because the second direction of the second process gas 110b does not point toward the second peripheral edge region 194. As a result, the deposition rate of the first and second process gases 110a and 110b near the second peripheral edge region 194 may decrease. This may be advantageous as the second peripheral edge region 194 that defines the maximum distance D₂ may otherwise be susceptible to relatively greater amounts of epitaxial material.

In other examples, the first and second gas inlet ports 106a and 106b may be oriented to increase cross-flow interaction between the first and second process gases 110a and 110b near the second peripheral edge region 194 of the wafer 104 where a greater amount of epitaxial material may otherwise be deposited due to the maximum distance D₂ of the peripheral edge 146 from the sidewall 152. Increasing the cross-flow interaction between the first and second process gases 110a and 110b at the second peripheral edge region 194 may be suitable where at least one of the process gases 110a and 110b includes an etchant gas (e.g., hydrogen chloride, HCl), such that a deposition rate of the first and second process gases 110a and 110b near the second peripheral edge region 194 of the wafer 104 may be decreased.

The angle of the second gas inlet port 106b to orient the second direction of the second process gas 110b may depend on the azimuthal angle 190. For example, the second gas inlet port 106b may be positioned such that the azimuthal angle 190 is about 90 degrees, and in such examples, the second gas inlet port 106b may be angled relative to the central axis of the susceptor 120 such that the second direction forms an angle between 15 degrees and 45 degrees, such as between 20 degrees and 40 degrees, or between 25 degrees and 35 degrees, such as 30 degrees, with the central axis of the susceptor 120. In other examples where the azimuthal angle 190 is greater than or less than 90 degrees, other angles of the second gas inlet port 106b may be used to target the same peripheral edge region of the wafer 104. Moreover, in some examples, the second gas inlet port 106b may substantially align with a diameter of the susceptor 120 and/or the wafer 104, and/or the first gas inlet port 106a may be angled relative to the central axis of the susceptor 120 as described above

As described above, the wafer 104 suitably rotates during processing. As a result, the orientation of the first and second gas inlet ports 106a and 106b to control flow interaction of the first and second process gases 110a and 110b near targeted regions of the wafer 104 (e.g., to increase flow interaction near the first peripheral edge region 192 and/or decrease flow interaction near the second peripheral edge region 194) may only be sufficient during a portion of the processing. As the wafer rotates, the second peripheral edge region 194 approaches the area where the flow interaction is purposely increased, and the first peripheral edge region 192 approaches the area where the flow interaction is purposely decreased. In general, it is difficult to alter the angle and/or orientation of the first and second gas inlet ports 106a and 106b during processing. Thus, to compensate for the rotation of the wafer 104 during processing, the flow rates of the process gas 110a and 110b may be modulated (e.g., via the controller 140).

The flow rates of the process gas 110a and 110b are suitably modulated such that deposition rate of the first and second process gases 110a and 110b increases near the first peripheral edge region 192 of the wafer 104 and the deposition rate of the first and second process gases 110a and 110b decreases near the second peripheral edge region 194. Moreover, the modulating the flow rates of the process gas 110a and 110b is suitably synchronized with rotation of the wafer 104. For example, as the wafer rotates, the flow rates of the process gas 110a and 110b may increase as the first peripheral edge region 192 approaches the area targeted by the angle and orientation of the first and second gas inlet ports 106a and 106b and the flow rates of the process gas 110a and 110b may decrease as the second peripheral edge region 194 approaches the area targeted by the angle and orientation of the first and second gas inlet ports 106a and 106b. Modulating the flow rates of the process gas 110a and 110b may additionally and/or alternatively include modulating the flow rates of specific process gases comprising the process gas 110a and/or 110b. For example, modulating the flow rates of the process gas 110a and 110b may include increasing a flow rate of a deposition precursor gas (e.g., trichlorosilane, TCS) included in the process gas 110a and/or 110b as the first peripheral edge region 192 approaches the area targeted by the angle and orientation of the first and second gas inlet ports 106a and 106b. Similarly, modulating the flow rates of the process gas 110a and 110b may include increasing a flow rate of an etchant gas (e.g., hydrogen chloride) included in the process gas 110a and/or 110b as the second peripheral edge region 194 approaches the area targeted by the angle and orientation of the first and second gas inlet ports 106a and 106b. In this way, the first peripheral edge region 192 is suitably targeted with greater quantities gases of process that deposit epitaxial material onto the front surface 142 of the wafer 104 and the second peripheral edge region is suitably targeted with greater quantities of etchant gases that smooth and/or remove epitaxial material deposited on the front surface 142 of the wafer 104.

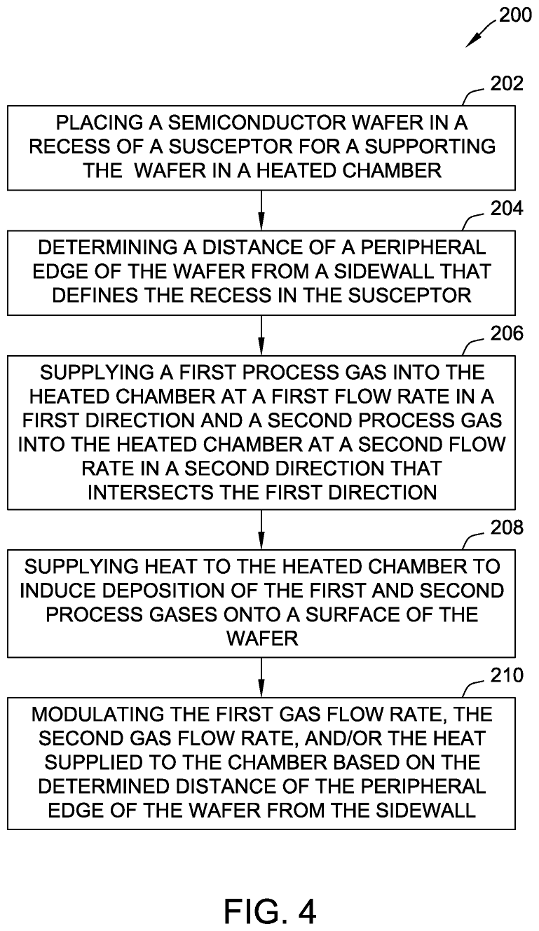

Referring now to FIG. 4, a process flow of an example method 200 of processing semiconductor wafers is shown. The method 200 includes placing 202 a semiconductor wafer 104 in a recess 150 of a susceptor 120. The susceptor 120 supports the wafer 104 within a processing environment 102 of a heated chamber 100. The recess 150 is defined in the front surface 148 of the susceptor 120 by a downwardly depending sidewall 152. The recess 150 is sized and shaped for receiving the wafer 104 therein. Suitably, the recess is sized and shaped such that a peripheral edge 146 of the wafer 104 is spaced a distance from the sidewall 152. Due to wafer placement tolerances, movement of the wafer during placement, thermal expansion, and/or other factors, the wafer 104 may not be perfectly centered such that variations in the distance between the peripheral edge 146 and the sidewall 152 exist along the circumferential extent of the wafer 104.

The method 200 also includes determining 204 a distance of the peripheral edge 146 of the wafer 104 from the sidewall 152. Suitably, the determining 204 includes determining a minimum distance D₁ of the peripheral edge 146 from the sidewall 152 and/or determining a maximum distance D₂ of the peripheral edge 146 from the sidewall 152. The distance of the peripheral edge 146 of the wafer 104 from the sidewall 152 may be determined, for example, by measurements collected by an optical sensor 158 (e.g., a camera) as described above. In some examples, the method 200 may include determining a peripheral edge region (e.g., a region 192) of the wafer 104 that is located the minimum distance D₁ from the sidewall 152. Additionally or alternatively, the method 200 may include determining a peripheral edge region (e.g., a region 194) of the wafer 104 that is located the maximum distance D₂ from the sidewall 152.

The method 200 also includes supplying 206 a first process gas 110a into the heated chamber 100 at a first gas flow rate in a first gas direction and a second process gas 110b into the heated chamber 100 at a second gas flow rate in a second gas direction that intersects the first gas direction. The first process gas 110a may be supplied by a first gas injection port 106a and the second process gas 110b may be supplied by a second gas injection port 106b. The first and second gas injection ports 106a and 106b may be angled and oriented such that the first and second process gas 110a and 110b intersect to create a cross-flow interaction within the processing environment 102 as described above.

The first process gas 110a may include one or more process gases. For example, the process gases may include deposition and/or etchant gases, such as for a selective epitaxial growth process, and the like. The first process gas 110a may include one or more deposition precursor gases, and optionally, one or more of a dopant precursor gas, an etchant gas, or a carrier gas. The deposition precursor gas may include a silicon precursor such as at least one of silane (SiH₄), disilane (Si₂H₆), dichlorosilane (H₂SiCl₂), and trichlorosilane (HCl₃Si). The dopant precursor gas may include at least one of germane (GeH₄), phosphine (PH₃), diborane (B₂H₆), arsine (AsH₃), or methylsilane (H₃CSiH₃). The etchant gas may include at least one of methane CH₄, a chloride-containing gas such as hydrogen chloride (HCL) and/or chlorine (Cl₂), or hydrogen fluoride (HF). The carrier gas may include at least one of nitrogen (N₂), argon (Ar), helium (He), or hydrogen (H₂).

To deposit a layer comprising silicon and germanium, the first process gas 110a may include dichlorosilane, germane, diborane, and hydrogen. To deposit a layer of silicon, the first process gas 110a one may include at least of silane, disilane, dichlorosilane, or trichlorosilane along with hydrogen chloride and hydrogen. To deposit doped silicon, the first process gas 110a may include the above gases and may further include at least one of phosphine, diborane, or arsine. To deposit a layer that includes silicon and carbon, the first process gas 110a may include disilane, methylsilane, germane, phosphine, and at least one of hydrogen chloride or chlorine in an environment comprising at least one of nitrogen or hydrogen.

The second process gas 110b may be the same or different from the first process gas 110a. The second process gas 110b may include any or all combinations of those gases discussed above for the first process gas (e.g., combinations of the deposition precursor gases, etchant gases, dopant precursor gases, and carrier gases). During a selective epitaxial growth process, for example, the second process gas 110b may include etchant gases, deposition precursor gases, or a combination thereof. The second process gas 110b may be flowed alternately, periodically, partially concurrently, or concurrently with the first process gas 110a.

The second process gas 110b may be different from the first process gas 110a, for example, to improve compositional uniformity in the deposited layer. The second process gas 110b may also be different from the first process gas 110a, for example, by providing a catalyst gas that catalyzes the first process gas 110a. For example, such catalyzation may improve compositional uniformity and/or thickness of a layer deposited on the wafer 104. The second process gas 110b may include the catalyst and other gases, for example, such as the silanes and/or germanes listed above. Example catalysts may include germane.

The method 200 also includes supplying 208 heat to the heated chamber 100 to induce deposition of the first and second process gases 110a and 110b onto a surface (e.g., a front surface 142) of the wafer 104. The heat may be supplied by radiant heating lamps 128 and/or spot heaters 170 as described above.

The method 200 also includes modulating 210 at least one of the first gas flow rate of the first process gas 110a, the second gas flow rate of the second process gas 110b, and the heat supplied to the heated chamber 100 to control a deposition rate of the first and second process gases 110a and 110b near the peripheral edge 146 of the wafer 104 based on the determined distance of the peripheral edge 146 of the wafer 104 from the sidewall 152. Suitably, modulating the at least one of the first gas flow rate, the second gas flow rate, and the heat supplied to the heated chamber 100 selectively increases or decreases the deposition rate of the first and second process gases 110a and 110b near the peripheral edge 146 of the wafer 104 based on the determined distance of the peripheral edge 146 of the wafer 104 from the sidewall 152.

For example, the method 200 may include modulating 210 the heat supplied to the heated chamber 100 to increase localized heating within the heated chamber 100 near a first peripheral edge region 192 of the wafer 104 that defines the minimum distance D₁ from the sidewall 152, and/or modulating the heat supplied to the heated chamber 100 to reduce localized heating within the heated chamber 100 near a second peripheral edge region 194 of the wafer 104 that defines the maximum distance D₂ from the sidewall. Suitably, modulating 210 the heat supplied to the heated chamber 100 increases a deposition rate of the first and second process gases 110a near the first peripheral edge region 192 and/or decreases the deposition rate of the first and second process gases 110a and 110b near the second peripheral edge region 194. Modulating 210 the heat supplied to the heated chamber 100 may include independently controlling the heating lamps 128 or radial zones thereof, or controlling one or more of the spot heaters 172 to produce radiant heat at targeted regions on the wafer 104 (e.g., at the peripheral edge region 192). A controller 140 may be used to modulate 210 the heat supplied to the heated chamber 100 by controlling the heating lamps 128 and/or the spot heaters 172 based on the determined 204 distance of the peripheral edge 146 of the wafer 104 from the sidewall 152. In some examples, the method 200 includes rotating the susceptor 120 and the wafer 104 and synchronizing the modulating 210 the heat supplied to the heated chamber 100 with rotation of the susceptor 120 and the wafer 104.

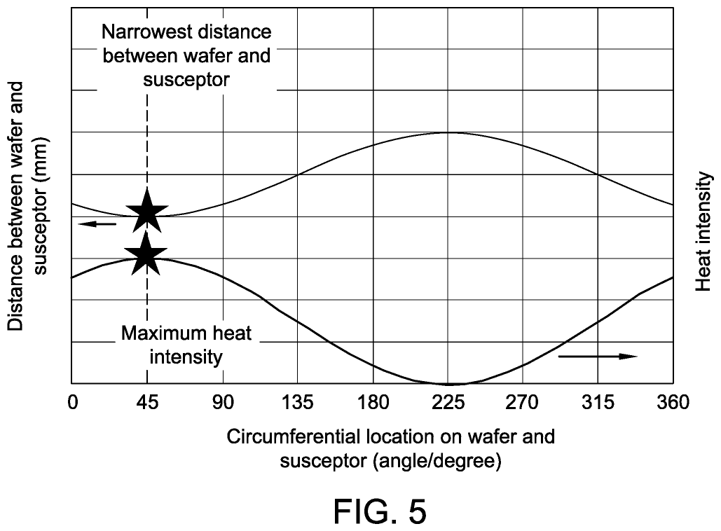

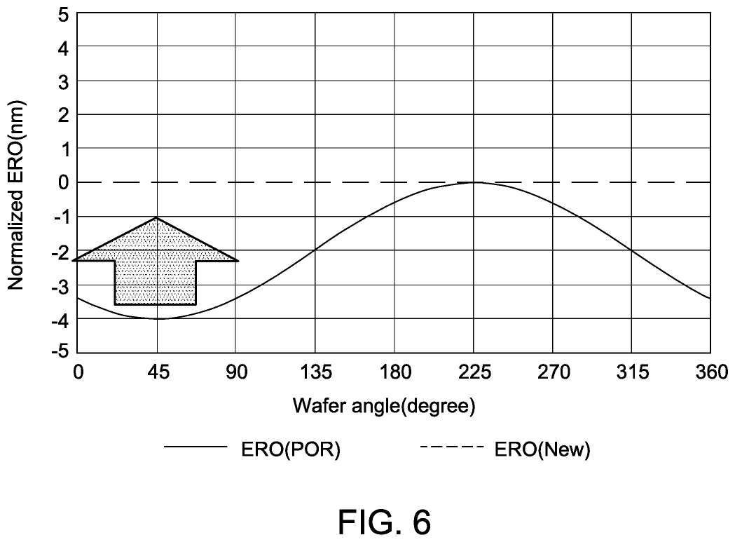

FIGS. 5 and 6 are provided to further illustrate modulating 210 the heat supplied to the heated chamber 100 based on the determined 204 distance between the peripheral edge 146 of the wafer 104 and the sidewall 152. FIG. 5 is a graph illustrating modulating 210 localized heating by spot heaters 172 within a heated chamber 100 based on the determined 204 distance between the peripheral edge 146 of the wafer 104 and the sidewall 152 of the susceptor 120. As shown in FIG. 5, the localized heating within the heated chamber 100 is increased at the region of the wafer 104 near where the distance between the peripheral edge 146 of the wafer and the sidewall 152 of the susceptor 120 is smallest. FIG. 6 is a graph that conceptually depicts normalized edge roll-off of epitaxial wafers that may be processed with and without modulating 210 the localized heating as illustrated in FIG. 5. As shown, compared to conventional processes (labeled ERO (POR) in FIG. 6), methods that include modulating 210 the localized heating based on the determined 204 distance (illustrated in FIG. 5, labeled EOR (New) in FIG. 6) may produce epitaxial wafers with better normalized edge-roll off. This may contribute to better uniformity in thickness and flatness of the epitaxial wafer.

Referring again to FIG. 4, the method 200 may additionally and/or alternatively include modulating 210 the first and/or second gas flow rates to achieve desired flow interaction (e.g., cross-flow interaction) between the first process gas 110a and the second process gas 110b near a peripheral edge region of the wafer 104 based on the determined 204 distance between the peripheral edge 146 and the sidewall 152. The controller 140 may be used to modulate 210 the first and/or second gas flow rates. For example, the first and/or second gas flow rates may be modulated 210 to increase flow interaction near the first peripheral edge region 192 of the wafer 104 and/or to reduce flow interaction near the second peripheral edge region 194 of the wafer 104 where the first and second process gas 110a and 110b include a deposition precursor gas. Additionally or alternatively, the first and/or second gas flow rates may be modulated 210 to increase flow interaction near the second peripheral edge region 194 of the wafer 104 where the first process gas 110a and/or the second process gas 110b includes an etchant gas.

As described above, the method 200 may also include rotating the susceptor 120 and the wafer 104, and modulating 210 the first and/or second gas flow rates is synchronized with a wafer rotational speed to control the deposition rate of the first and second process gases near targeted peripheral edge regions of the wafer 104 based on the determined 204 distance. For example, as the wafer 104 rotates, the first and/or second gas flow rates may be modulated 210 to increase as the first peripheral edge region 192 approaches the area targeted by an angle and orientation of the first and second gas inlet ports 106a and 106b and/or the first and/or second gas flow rates may be modulated 210 to decrease as the second peripheral edge region 194 approaches the area targeted by the angle and orientation of the first and second gas inlet ports 106a and 106b. As described above, modulating 210 the first and/or second gas flow rates may additionally and/or alternatively include modulating 210 the flow rates of specific process gases (e.g., deposition precursor gas (es) and/or etchant gas (es)) comprising the process gas 110a and/or 110b. The flow rates of the specific process gases may be modulated 210 based on the targeted peripheral edge region of the wafer 104 that is subjected to the bulk of the flow interaction between the first and second process gases 110a and 110b at specific stages of the deposition process. This may change as the wafer 104 is rotated during processing. Thus, when, for example, the first peripheral edge region 192 of the wafer 104 is subjected to the bulk of the flow interaction between the first and second process gases 110a and 110b, the first and/or second gas flow rates may be modulated to increase a flow rate of a deposition precursor gas (e.g., trichlorosilane, TCS). When, for example, the second peripheral edge region 194 of the wafer 104 is subjected to the bulk of the flow interaction between the first and second process gases 110a and 110b, the first and/or second gas flow rates may be modulated to increase a flow rate of an etchant gas (e.g., hydrogen chloride, HCl).

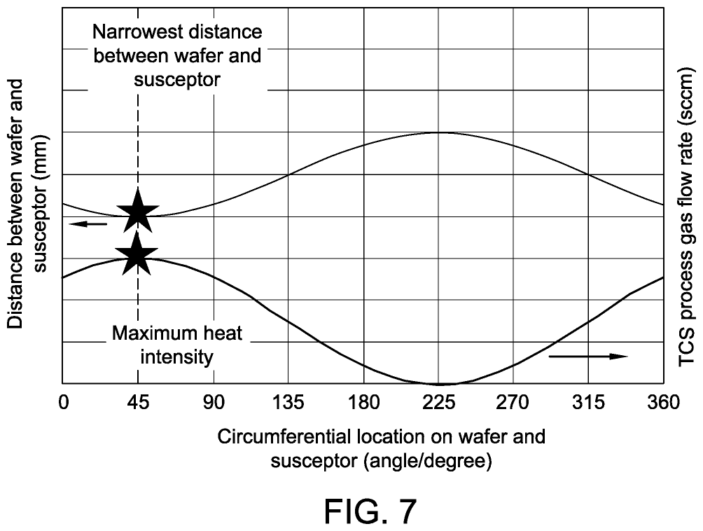

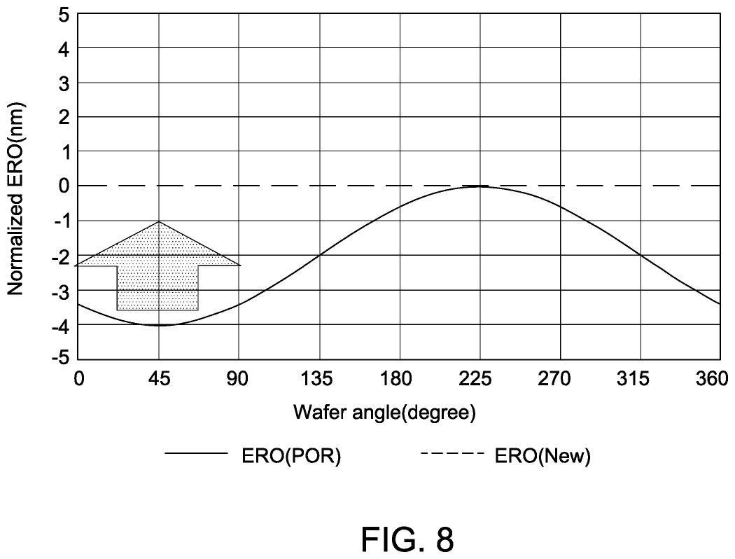

FIGS. 7-10 are provided to further illustrate modulating 210 the first and/or second gas flow rates based on the determined 204 distance between the peripheral edge 146 of the wafer 104 and the sidewall 152. FIG. 7 is a graph illustrating modulating 210 a flow rate of trichlorosilane (TCS) process gas within a heated chamber 100 based on the determined 204 distance between the peripheral edge 146 of the wafer 104 and the sidewall 152 of the susceptor 120. As shown in FIG. 7, the flow rate of the TCS process gas is increased at the region of the wafer 104 near where the distance between the peripheral edge 146 of the wafer and the sidewall 152 of the susceptor 120 is smallest. FIG. 8 is a graph that conceptually depicts normalized edge roll-off of epitaxial wafers that may be processed with and without modulating 210 the flow rate of the TCS process gas as illustrated in FIG. 7. As shown, compared to conventional processes (labeled ERO (POR) in FIG. 8), methods that include modulating 210 the flow rate of TCS process gas based on the determined 204 distance (illustrated in FIG. 7, labeled EOR (New) in FIG. 8) may produce epitaxial wafers with better normalized edge-roll off. This may contribute to better uniformity in thickness and flatness of the epitaxial wafer.

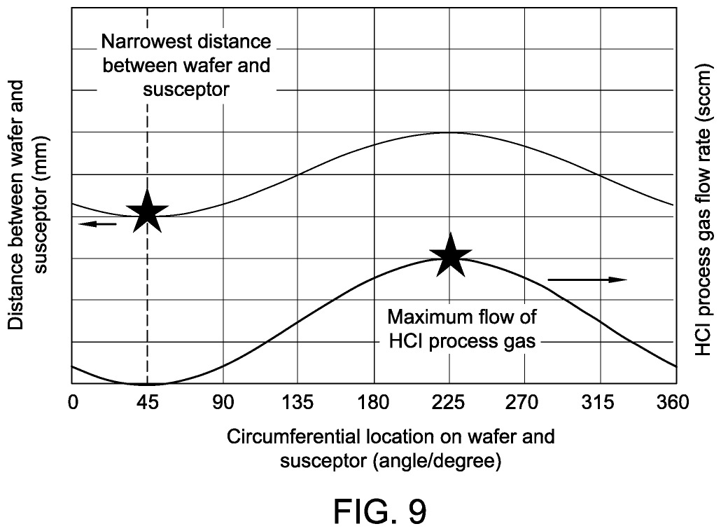

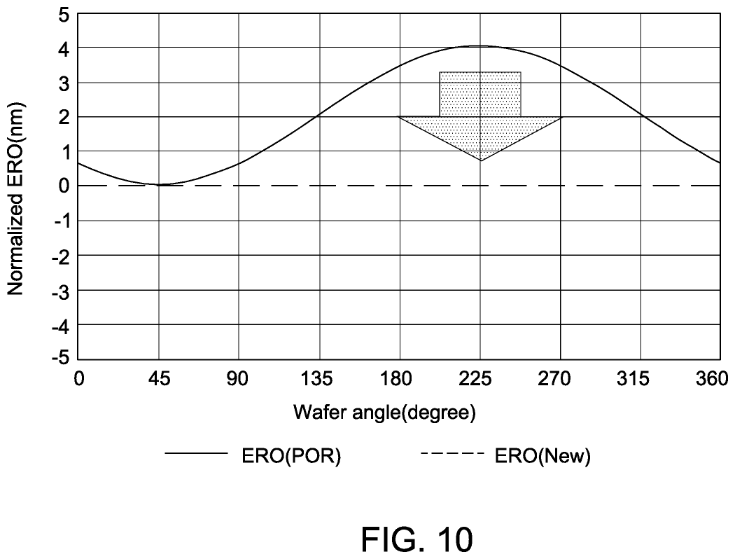

FIG. 9 is a graph illustrating modulating 210 a flow rate of hydrogen chloride (HCl) process (or etchant) gas flow within a heated chamber 100 based on the determined 204 distance between the peripheral edge 146 of the wafer 104 and the sidewall 152. As shown in FIG. 9, the flow rate of the HCl etchant gas is increased at the region of the wafer 104 near where the distance between the peripheral edge 146 of the wafer and the sidewall 152 of the susceptor 120 is greatest. The flow rate of the HCl etchant gas is decreased at the region of the wafer 104 near where the distance between the peripheral edge 146 of the wafer and the sidewall 152 of the susceptor 120 is smallest. FIG. 10 is a graph that conceptually depicts normalized edge roll-off of epitaxial wafers that may be processed with and without modulating 210 the flow rate of HCl etchant gas as illustrated in FIG. 9. As shown, compared to conventional processes (labeled ERO (POR) in FIG. 10), methods that include modulating 210 the flow rate of HCl etchant gas based on the determined 204 distance (illustrated in FIG. 9, labeled EOR (New) in FIG. 10) may produce epitaxial wafers with better normalized edge-roll off. This may contribute to better uniformity in thickness and flatness of the epitaxial wafer.

Example systems and methods for depositing a layer (e.g., an epitaxial layer) on semiconductor wafers within a heated chamber are described above and enable controlling processing conditions during deposition based on wafer placement within the heated chamber. In particular, the semiconductor wafer is supported in the heated chamber on a susceptor, and the systems and methods described facilitate controlling deposition behavior that may otherwise be influenced by an off-centered position of the semiconductor wafer within a recess of the susceptor. It has been discovered that the distance between the periphery of the wafer and a recess sidewall of the susceptor may negatively impact the uniform thickness of the deposited layer and, thereby, flatness of the processed wafer. In particular, a greater distance between the wafer peripheral edge and the recess sidewall may cause an uptick in deposited layer thickness near the wafer peripheral edge, and a smaller distance between the wafer peripheral edge and the sidewall may cause a downtick in deposited layer thickness near the wafer peripheral edge. As such, when the semiconductor wafer is off-centered within the recess and the distance between the wafer peripheral edge and the recess sidewall varies circumferentially along the wafer, the deposited layer may have upticks and downticks near the wafer peripheral edge that result in non-uniform thickness and poor flatness of the processed wafer. Centering the wafer in the recess is limited by wafer placement tolerances, movement of the wafer during placement, thermal expansion, and/or other limitations, and may not be adequately controlled to mitigate or prevent such deposition behavior near the wafer peripheral edge.

Accordingly, in the examples described above, a distance between the wafer peripheral edge and the recess sidewall of the susceptor is determined and processing conditions are modulated based on this determination. For example, a flow rate of process gas introduced to a processing environment of the heated chamber and/or heat supplied to the processing environment may be modulated to selectively control a deposition rate at certain wafer peripheral edge regions depending on the distance between the peripheral edge and the recess sidewall. At wafer peripheral edge regions located a relatively smaller distance from the recess sidewall, the processing conditions (e.g., process gas flow rate and/or heat intensity) may be modulated to selectively increase a deposition rate at these regions. At wafer peripheral edge regions located a relatively greater distance from the recess sidewall, the processing conditions (e.g., process gas flow rate and/or heat intensity) may be modulated to selectively decrease a deposition rate at these regions. Localized heating control, for example, using one or more spot heaters, and/or cross-flow interaction between process gases within the processing environment, may be utilized to provide greater control over the selective increase and/or decrease in deposition rate at certain wafer peripheral edge regions based on the distance from the recess sidewall. In this way, epitaxial wafers with improved edge-roll off and better uniformity in thickness and flatness of the epitaxial wafer may be produced with greater throughput and in a cost-effective manner.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present invention or the embodiment (s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A method of processing semiconductor wafers within a heated chamber that includes a susceptor for supporting a semiconductor wafer, the susceptor having a front surface and a recess defined in the front surface by a downwardly depending sidewall, the method comprising:
placing a semiconductor wafer in the recess of the susceptor;
determining a distance of a peripheral edge of the wafer from the sidewall;
supplying a first process gas into the heated chamber at a first gas flow rate in a first gas direction and a second process gas into the heated chamber at a second gas flow rate in a second gas direction that intersects the first gas direction;
supplying heat to the heated chamber to induce deposition of the first and second process gases onto a surface of the wafer; and
modulating at least one of the first gas flow rate, the second gas flow rate, and the heat supplied to the heated chamber to control a deposition rate of the first and second process gases near the peripheral edge of the wafer based on the determined distance of the peripheral edge of the wafer from the sidewall.

2. The method of claim 1, further comprising determining at least one of a minimum distance of the peripheral edge of the wafer from the sidewall and a maximum distance of the peripheral edge of the wafer from the sidewall.

3. The method of claim 2, further comprising modulating the heat supplied to the heated chamber to increase localized heating within the heated chamber near a peripheral edge region of the wafer that defines the minimum distance from the sidewall.

4. The method of claim 2, further comprising modulating the heat supplied to the heated chamber to reduce localized heating within the heated chamber near a peripheral edge region of the wafer that defines the maximum distance from the sidewall.

5. The method of claim 2, further comprising modulating at least one of the first gas flow rate and the second gas flow rate to increase flow interaction between the first process gas and the second process gas near a peripheral edge region of the wafer that defines the minimum distance from the sidewall.

6. The method of claim 2, further comprising modulating at least one of the first gas flow rate and the second gas flow rate to reduce flow interaction between the first process gas and the second process gas near a peripheral edge region of the wafer that defines the maximum distance from the sidewall.

7. The method of claim 1, further comprising rotating the wafer during the supplying the first and second process gases and the supplying the heat, wherein the modulating the at least one of the first gas flow rate, the second gas flow rate, and the heat supplied to the heated chamber is synchronized with a wafer rotational speed to control the deposition rate of the first and second process gases near the peripheral edge of the wafer based on the determined distance of the peripheral edge of the wafer from the sidewall.

8. The method of claim 1, wherein the first and second process gases comprise a deposition precursor gas and an etchant gas.

9. The method of claim 8, further comprising determining a minimum distance of the peripheral edge of the wafer from the sidewall.

10. The method of claim 9, further comprising modulating at least one of the first gas flow rate and the second gas flow rate to increase flow of the deposition precursor gas near a peripheral edge region of the wafer that defines the minimum distance from the sidewall.

11. The method of claim 9, further comprising modulating at least one of the first gas flow rate and the second gas flow rate to decrease flow of the etchant gas near a peripheral edge region of the wafer that defines the minimum distance from the sidewall.

12. The method of claim 1, wherein the modulating the at least one of the first gas flow rate, the second gas flow rate, and the heat supplied to the heated chamber selectively increases the deposition rate of the first and second process gases near peripheral edge regions of the wafer located a relatively greater distance from the sidewall.

13. A method of processing semiconductor wafers within a heated chamber that includes a susceptor for supporting a semiconductor wafer, the susceptor having a front surface and a recess defined in the front surface by a downwardly depending sidewall, the method comprising:
placing a semiconductor wafer in the recess of the susceptor;
determining a peripheral edge region of the wafer that is located a minimum distance from the sidewall;
supplying a first process gas into the heated chamber at a first gas flow rate in a first gas direction and a second process gas into the heated chamber at a second gas flow rate in a second gas direction that intersects the first gas direction; and
modulating at least one of the first gas flow rate and the second gas flow rate to selectively increase a deposition rate of the first and second process gases near the peripheral edge region of the wafer that is located the minimum distance from the sidewall.

14. The method of claim 13, wherein the first and second process gases comprise a deposition precursor gas and an etchant gas.

15. The method of claim 14, wherein the modulating the at least one of the first gas flow rate and the second gas flow rate comprises increasing a flow rate of the deposition precursor gas near the peripheral edge region of the wafer that is located the minimum distance from the sidewall.

16. The method of claim 14, wherein the modulating the at least one of the first gas flow rate and the second gas flow rate comprises decreasing a flow rate of the etchant gas near the peripheral edge region of the wafer that is located the minimum distance from the sidewall.

17. A method of processing semiconductor wafers within a heated chamber that includes a susceptor for supporting a semiconductor wafer, the susceptor having a front surface and a recess defined in the front surface by a downwardly depending sidewall, the method comprising:
placing a semiconductor wafer in the recess of the susceptor;
determining a peripheral edge region of the wafer that is located a minimum distance from the sidewall;
supplying process gas into the heated chamber;
supplying heat to the heated chamber to induce deposition of the process gas onto a surface of the wafer; and
modulating the heat supplied to the heated chamber to selectively increase a deposition rate of the process gas near the peripheral edge region of the wafer that is located the minimum distance from the sidewall.

18. The method of claim 17, further comprising rotating the susceptor and synchronizing the modulating the heat supplied to the heated chamber with rotation of the susceptor.

19. The method of claim 17, wherein modulating the heat supplied to the heated chamber comprises selectively increasing localized heating within the heated chamber near the peripheral edge region that is located the minimum distance from the sidewall.

20. The method of claim 17, wherein modulating the heat supplied to the heated chamber comprises modulating one or more spot heaters to selectively increase localized heating supplied by the one or more spot heaters to the peripheral edge region of the wafer that is located the minimum distance from the sidewall.
